(19) United States
(12) Patent Application Publication
(10) Pub. No.: US 2008/0135915 A1
(43) Pub. Date: Jun. 12, 2008

(54) Non-volatile memory and method of fabricating the same

(75) Inventors: Ing-Ruey Liaw, Hsinchu (TW); Thomas Chang, Taichung (TW)

Correspondence Address: BIRCH STEWART KOLASCH & BIRCH, PO BOX 747, FALLS CHURCH, VA, 22040-0747, US

(73) Assignee: Vanguard International Semiconductor Corporation

(21) Appl. No.: 11/785,853

(22) Filed: Apr. 20, 2007

(30) Foreign Application Priority Data
Dec. 12, 2006 (TW) 95146438

(51) Int. Cl. H01L 21/336; H01L 21/8238

(52) U.S. Cl. 257/316; 438/264; 257/E21.409; 257/E21.683

(57) ABSTRACT

A non-volatile memory and method of fabricating the same are provided. The method of fabricating a non-volatile memory comprises forming a tunnel insulating layer, a first conductive layer and a first patterned hard mask layer on a semiconductor substrate sequentially. A first conductive pattern is formed by etching the first conductive layer using the first patterned hard mask layer as a mask. The first patterned hard mask layer is removed. A second patterned hard mask layer is formed on an edge of the first conductive pattern. A pair of opposing spacers is formed on sidewalls of the second patterned hard mask layer. The first conductive pattern is etched using the second patterned hard mask layer and the spacers as masks to form a pair of stacked structures comprising the spacers, the second patterned hard mask layer and the remaining first conductive pattern. A pair of inter gate insulating layers are formed on sidewalls of the first conductive pattern. A control gate insulating layer is formed on the semiconductor substrate between the pair of inter gate insulating layers. A control gate is formed on the control gate insulating layer.

### BACKGROUND OF THE INVENTION

1. Field of the Invention

The invention relates to a non-volatile memory and method of fabricating the same, and more particularly to a dual bit non-volatile memory and method of fabricating the same.

2. Description of the Related Art

A flash memory is a kind of non-volatile memory. Generally speaking, a flash memory comprises two gates, the first gate is a floating gate for data storage and the second gate is a control gate for data input/output. The floating gate is placed under the control gate and “floats”. Floating refers to isolating the floating gate surrounding it with insulating materials for preventing charge loss. The control gate is connected to a word line (WL) for device control. One advantage of flash memories is block-by-block erasing. Flash memories are widely used in consumer electronic products, for example, digital cameras, digital videos, mobile phones, desktops, mobile audio players and personal digital assistants (PDA).

In conventional non-volatile memory fabricating methods, a masking process defines elements. Elements with narrow width are frequently misaligned resulting in broken and short circuits due to mask limitations. Electrical performance in conventional non-volatile memory is thus hindered. Device dimensions of conventional non-volatile memory are limited by design rules, thus, scaling down devices is difficult.

### BRIEF SUMMARY OF INVENTION

A detailed description is given in the following embodiments with reference to the accompanying drawings.

A non-volatile memory and method for fabricating the same are provided. The method for fabricating a non-volatile memory comprises sequentially forming a tunnel insulating layer, a first conductive layer and a first patterned hard mask layer on a semiconductor substrate. A first conductive pattern is formed by etching the first conductive layer using the first patterned hard mask layer as a mask. The first conductive pattern is then removed. A second patterned hard mask layer is formed on an edge of the first conductive pattern. A pair of opposing spacers is formed on sidewalls of the second patterned hard mask layer. The first conductive pattern is etched using the second patterned hard mask layer and the spacers as masks to form a pair of stacked structures comprising the spacers, the second patterned hard mask layer and the remaining first conductive pattern. A pair of inter gate insulating layers are formed on sidewalls of the first conductive pattern. A control gate insulating layer is formed on the semiconductor substrate between the pair of inter gate insulating layers. A control gate is formed on the control gate insulating layer.

An exemplary embodiment of a non-volatile memory comprises a semiconductor substrate with a plurality of shallow trench isolations. A pair of opposing floating gate structures is placed on the semiconductor substrate. A pair of sidewalls of the pair of floating gate structures is aligned to an edge of the shallow trench isolation. Each of the floating gate structures comprises a tunnel insulating layer, a spacer and a floating gate. A pair of inter gate insulating layers are placed on the other sidewalls of the floating gate structures. A control gate insulating layer are placed on the semiconductor substrate between the pair of inter gate insulating layers. A control gate is conformally formed over the control gate insulating layer.

### BRIEF DESCRIPTION OF DRAWINGS

The invention can be more fully understood by reading the subsequent detailed description and examples with references made to the accompanying drawings, wherein:

FIG. 1 is a top view of an exemplary embodiment of a non-volatile memory.

FIGS. 2, 3a, 4a, 5-11 and 12a are cross sections taken along line A-A′ of FIG. 1.

FIGS. 3b, 4b and 12b are cross sections taken along line B-B′ of FIG. 1.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

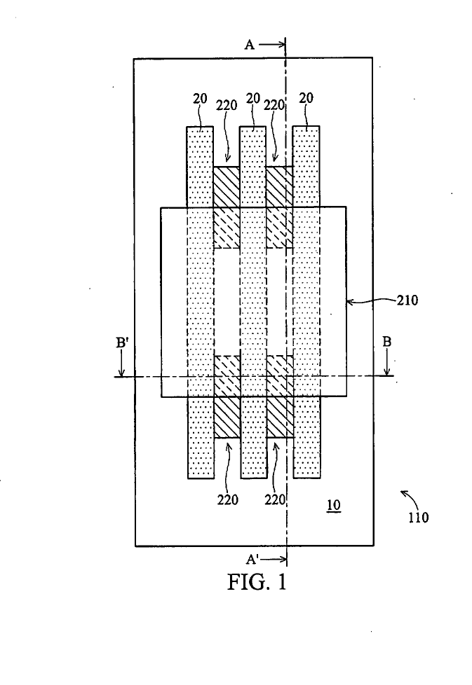

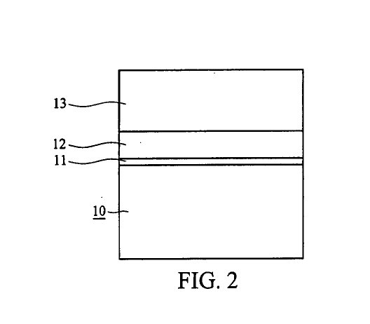

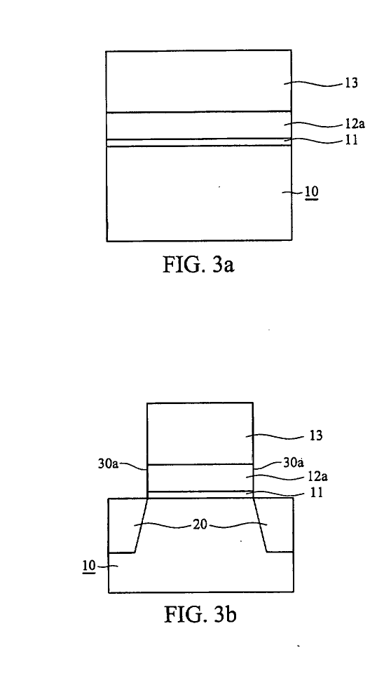

FIG. 1 is a top view of an exemplary embodiment of a non-volatile memory 110. FIGS. 2, 3a, 4a, 5-11 and 12a are cross sections taken along line A-A′ of FIG. 1. FIGS. 3b, 4b and 12b are cross sections taken along line B-B′ of FIG. 1. Wherever possible, the same reference numbers are used in the drawings and the descriptions to the same or like parts.

FIG. 1 illustrates a top view of an exemplary embodiment of non-volatile memory 110. The non-volatile memory 110 comprises a pair of separate floating gate structures 220 and a control gate structure 210 for dual bit data storage. Each of the non-volatile memories 110 is isolated by shallow trench isolations (STI) 20.

FIGS. 2, 3a, 4a, 5-11 and 12a are cross sections of an exemplary embodiment of the non-volatile memory 110 taken along line A-A′ of FIG. 1. FIGS. 3b, 4b and 12b are cross sections taken substantially along line B-B′ of FIG. 1. FIG. 2 illustrates sequentially forming a tunnel insulating layer 11, a first conductive layer 12 and a first patterned hard mask layer 13 over a semiconductor substrate 10. The tunnel insulating layer II may be a silicon dioxide (SiO₂) layer formed by thermal oxidation, atmospheric pressure chemical vapor deposition (APCVD) or low pressure CVD (LPCVD) with a thickness of about 70 Å to 100 Å. The first conductive layer 12 may be a polysilicon layer formed by CVD with a thickness of about 1000 Å to 3000 Å. The first patterned hard mask layer 13 may be a silicon nitride (Si₃N₄) layer with a thickness of about 1000 Å to 3000 Å. Next, referring to FIGS. 3a and 3b, a first conductive pattern 12a is formed by etching the first conductive layer 12 using the first patterned hard mask layer 13 as a mask. In one embodiment, the first conductive layer 12 is etched by STI process. A trench (not shown) is formed in the semiconductor substrate 10 to define an active region (not shown) during the step of etching the first conductive layer 12. A liner layer and an insulating layer such as an oxide layer are formed by high density plasma CVD (HDP CVD) or CVD in the trench in sequence. The insulating layer is then planarized by chemical mechanical polishing (CMP) using the first patterned hard mask layer 13 as a mask. Finally, the first patterned hard mask layer 13 is removed by wet etching, such as submersion in hot phosphoric acid (H₃PO₄), to form shallow trench isolations (STI 20. As shown in FIG. 3b, the first conductive pattern 12a is formed in same step as shallow trench isolations (STI) 20, thus a photolithography process for the first conductive pattern 12a can be eliminated. Additionally, a width of the first conductive pattern 12a can be scaled down by STI, and a device current leakage problem due to alignment shift of the conductive pattern 12a on the shallow trench isolations (STI) 20 can be avoided.

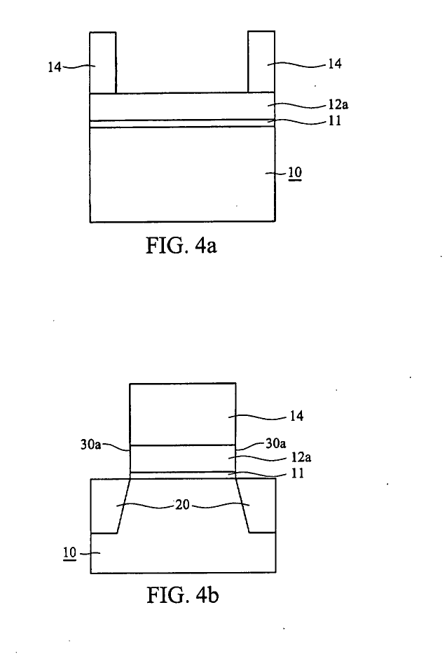

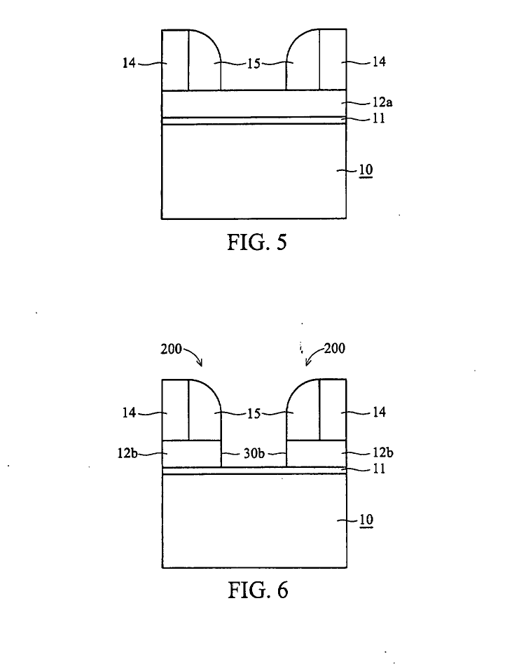

Referring to FIGS. 4a and 4b, a second patterned hard mask layer 14 such as silicon nitride (Si₃N₄) with a thickness of about 1000 Å to 3000 Å is formed over the edge of the first conductive pattern 12a. As shown in FIG. 5, a pair of spacers 15 are then formed on sidewalls of the second patterned hard mask layer 14 and face each other. The spacers 15 may be formed of silicon dioxide (SiO₂) using tetraethoxysilane (TEOS) as a reactive gas. In some embodiments, the spacers 15 are formed by depositing SiO₂ and following an etching back process. The second patterned hard mask layer 14 and the spacers 15 preferably have an etching selectivity of about 2 to 10 or greater than 10.

Referring to FIG. 6, the first conductive pattern 12a is etched using the second patterned hard mask layer 14 and the spacers 15 as masks to form a pair of stacked structures 200. Each of the stacked structure 200 comprises the spacer 15, the second patterned hard mask layer 14 and the remaining first conductive pattern 12b. Subsequent to forming the stacked structure 200, a sidewall 30b of the remaining first conductive pattern 12b is self-aligned to the spacers 15.

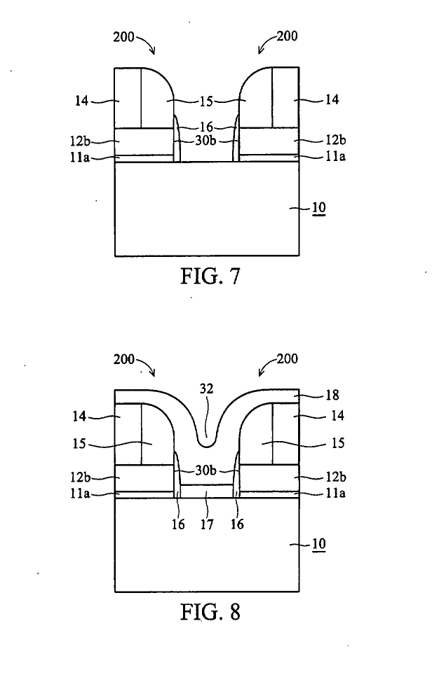

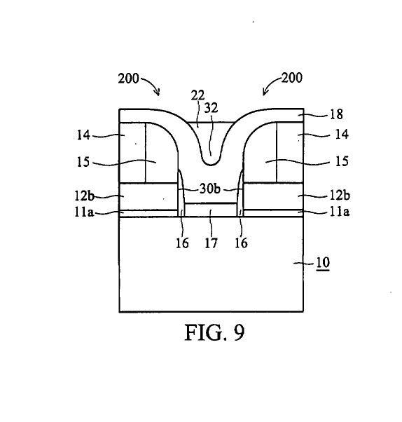

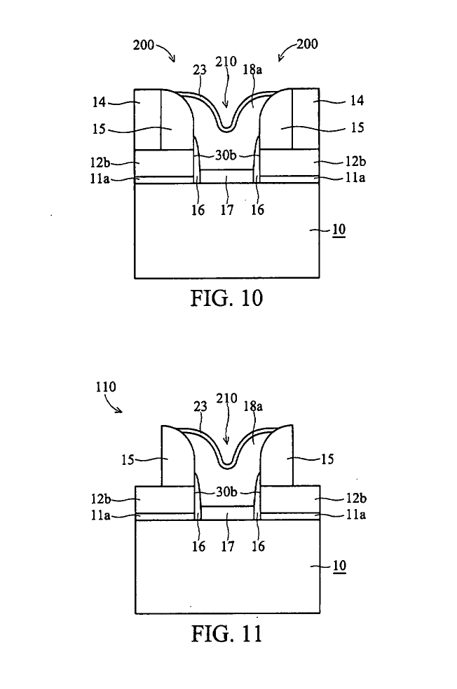

As shown in FIG. 7, a pair of inter gate insulating layers 16 are formed on the sidewalls 30b of the first conductive patterns 12b and faced each other. The inter gate insulating layers 16 may be formed by depositing an oxide layer (not shown) and following an etching back process or by thermal oxidation. The inter gate insulating layers 16 has utilities for protecting and isolating the first conductive pattern 12b. The inter gate insulating layers 16 may be an oxide layer such as silicon dioxide (SiO₂). Referring to FIG. 8, a control gate insulating layer 17 is formed on the semiconductor substrate 10 between the pair of inter gate insulating layers 16 by thermal oxidation or CVD. The control gate insulating layer 17 may comprise silicon dioxide (SiO₂), oxide-nitride-oxide (ONO), nitride-oxide (NO), tantalum oxide (Ta₂O₅) or silicon nitride (Si₃N₄). Next, a second conductive layer 18 with a recess 32 is conformally formed over the control gate insulating layer 17. As shown in FIG. 9, a sacrificial material such as photoresist or organic anti-reflective coating (ARC) is filled in the recess by spin-coating. This is an optional process and can be omitted if the recess 32 has very small dimensions. Next, referring to FIG. 10, the second conductive layer 18 is etched using the sacrificial material 22 as a mask. Finally, the sacrificial material 22 is removed to form a self-aligned control gate 18a. Alternatively, the control gate 18a may be formed by photolithography and etching processes. A passivation layer 23 is formed over the control gate 18a by an oxidation process. A control gate structure 210 is then formed. The control gate structure 210 comprises the inter gate insulating layers 16, the control gate insulating layer 17 and the control gate 18a.

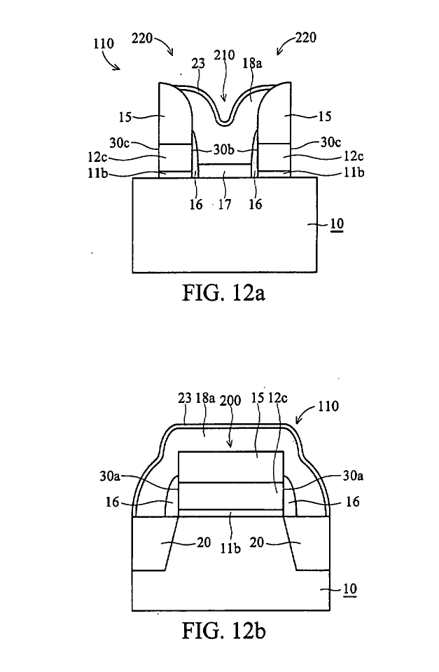

Referring to FIG. 11, the second patterned hard mask layer 14 is removed by submersion in hot phosphoric acid (H₃PO₄) for example. Next, referring to FIG. 12a, the remaining first conductive pattern 12b and the tunnel insulating layer 11a are etched to form a pair of self-aligned floating gates 220 using the spacers 15 as masks. After the etching process, another sidewall 30c of the floating gate 12c is self-aligned to the spacer 15. The floating gate 220 comprises the spacer 15, the floating gate 12c and the tunnel insulating layer 11b. An exemplary embodiment of forming the non-volatile memory 110 is thus complete. As shown in FIG. 12b, a sidewall 30a of the separated floating gate 12c is self-aligned to an edge of the STI 20, thus, the photolithography process for forming a floating gate can be eliminated. Additionally, current leakage problems arising from an alignment shift of the floating gate 12c to the shallow trench isolations (STI) 20 can be prevented.

An exemplary embodiment of the non-volatile memory 110 is a dual bit non-volatile memory with separate floating gates formed before the control gate. Some advantages of the non-volatile memory 110 are described in the following. A sidewall of the floating gate is self-aligned to the STI edge, thus, a width of the floating gate can be scaled down by STI and is not limited by critical dimensions (CD) of the mask. A sidewall of the floating gate is self-aligned to the spacer, and critical dimensions (CD) of the floating gate are defined by thickness of the spacer. A mask process for floating gate can be eliminated and the rigid square shape of the floating gate maintained. 3. The control gate is self-aligned to the region between the separate floating gates. A mask process for the control gate can be eliminated, and the control gate CD is control gate is not limited by the mask CD.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a non-volatile memory, comprising:
sequentially forming a tunnel insulating layer, a first conductive layer and a first patterned hard mask layer on a semiconductor substrate;
forming a first conductive pattern by etching the first conductive layer using the first patterned hard mask layer as a mask;
removing the first patterned hard mask layer;
forming a second patterned hard mask layer on an edge of the first conductive pattern;
forming a pair of opposing spacers on sidewalls of the second patterned hard mask layer;
etching the first conductive pattern using the second patterned hard mask layer and the spacers as masks to form a pair of stacked structures comprising the spacers, the second patterned hard mask layer and the remaining first conductive pattern;
forming a pair of inter gate insulating layers on sidewalls of the first conductive pattern
forming a control gate insulating layer on the semiconductor substrate between the pair of inter gate insulating layers; and
forming a control gate on the control gate insulating layer between the pair of stacked structures.

2. The method of fabricating the non-volatile memory as claimed in claim 1, further comprising:
forming a trench in the semiconductor substrate to define an active region in the same step the first conductive layer is etched.

3. The method of fabricating the non-volatile memory as claimed in claim 2, further comprising:
filling an insulating layer in the trench to form a shallow trench isolation (STI).

4. The method of fabricating the non-volatile memory as claimed in claim 1, wherein the first conductive layer or the control gate is a polysilicon layer.

5. The method of fabricating the non-volatile memory as claimed in claim 1, wherein the first patterned hard mask layer or the second patterned hard mask layer is a silicon nitride layer.

6. The method of fabricating the non-volatile memory as claimed in claim 1, wherein the tunnel insulating layer, the spacer or the inter gate insulating layers is an oxide layer.

7. The method of fabricating the non-volatile memory as claimed in claim 1, wherein the second patterned hard mask layer and the spacers have an etching selectivity of about 2 to 10.

8. The method of fabricating the non-volatile memory as claimed in claim 1, further comprising:
depositing an insulating layer;
performing a etching back process to form the pair of inter gate insulating layers.

9. The method of fabricating the non-volatile memory as claimed in claim 1, wherein the inter gate insulating layers are formed by thermal oxidation.

10. The method of fabricating the non-volatile memory as claimed in claim 1, wherein the control gate insulating layer are formed by thermal oxidation or chemical vapor deposition (CVD).

11. The method of fabricating the non-volatile memory as claimed in claim 1, wherein the control gate insulating layer comprises silicon dioxide (SiO₂), oxide-nitride-oxide (ONO), nitride-oxide (NO), tantalum oxide (Ta₂O₅) or silicon nitride (Si₃N₄).

12. The method of fabricating the non-volatile memory as claimed in claim 1, further comprising:
conformally forming a second conductive layer with a recess over the control gate insulating layer;
filling a sacrificial material in the recess by spin-coating;
etching the second conductive layer using the sacrificial material as a mask; and
removing the sacrificial material to form the control gate.

13. The method of fabricating the non-volatile memory as claimed in claim 1, wherein the control gate is formed by photolithography and etching processes.

14. The method of fabricating the non-volatile memory as claimed in claim 12, wherein the second conductive layer is a polysilicon layer.

15. The method of fabricating the non-volatile memory as claimed in claim 12, wherein the sacrificial material is organic.

16. The method of fabricating the non-volatile memory as claimed in claim 12, wherein the sacrificial material comprises photoresist or organic anti-reflective coating (ARC).

17. The method of fabricating the non-volatile memory as claimed in claim 1, further comprising:
forming a passivation layer over the control gate;
removing the second patterned hard mask layer; and
etching the remaining first conductive pattern and the tunnel insulating layer to form a pair of the floating gates using the spacers as masks.

18. The method of fabricating the non-volatile memory as claimed in claim 17, wherein the passivation layer is a thermal oxide layer.

19. A non-volatile memory, comprising:
a semiconductor substrate with a plurality of shallow trench isolations;
a pair of floating gate structures placed on the semiconductor substrate and faced each other, a pair of sidewalls of the pair of floating gate structures are aligned to an edge of the shallow trench isolation, each of the floating gate structures comprises a tunnel insulating layer, a spacer and a floating gate;
a pair of inter gate insulating layers placed on the other sidewalls of the floating gate structures;
a control gate insulating layer placed on the semiconductor substrate between the pair of inter gate insulating layers; and
a control gate conformally placed over the control gate insulating layer.

20. The non-volatile memory as claimed in claim 19, wherein the floating gate or the control gate is a polysilicon layer.

21. The non-volatile memory as claimed in claim 19, wherein the tunnel insulating layer, the spacers or the inter gate insulating layers is an oxide layer.

22. The non-volatile memory as claimed in claim 19, wherein the control gate insulating layer comprises silicon dioxide (SiO₂), oxide-nitride-oxide (ONO), nitride-oxide (NO), tantalum oxide (Ta₂O₅) or silicon nitride (Si₃N₄).

23. The non-volatile memory as claimed in claim 19, wherein an etching back process forms the control gate.

24. The non-volatile memory as claimed in claim 19, wherein the control gate is formed by photolithography and etching processes.

25. The non-volatile memory as claimed in claim 19, further comprising a passivation layer formed over the control gate.

26. The non-volatile memory as claimed in claim 19, wherein the passivation layer is a thermal oxide layer.
